(19) United States
(12) Patent Application Publication
(10) Pub. No.: US 2011/0277833 A1
(43) Pub. Date: Nov. 17, 2011

(54) BACKSIDE CONTACT SOLAR CELL

(75) Inventors: Michael N. Miller, Austin, TX (US); Sidlgata V. Sreenivasan, Austin, TX (US); Frank Y. Xu, Round Rock, TX (US); Gerard M. Schmid, Austin, TX (US)

(73) Assignee: Molecular Imprints, Inc., Austin, TX (US)

(21) Appl. No.: 13/105,695

(22) Filed: May 11, 2011

Related U.S. Application Data
(60) Provisional application No. 61/333,621, filed on May 11, 2010.

(51) Int. Cl. H01L 31/0224; H01L 31/0232

(52) U.S. Cl. 136/256; 438/69; 257/E31.127

(57) ABSTRACT

Variations of interdigitated backside contact (IBC) solar cells having patterned areas formed using nano imprint lithography are described.

### CROSS-REFERENCE TO RELATED APPLICATIONS

This application claims the benefit under 35 U.S.C. §119(e)(1) of U.S. Provisional Patent Application No. 61/333,621 filed May 11, 2010, which is hereby incorporated by reference herein in its entirety.

### BACKGROUND INFORMATION

Nano-fabrication includes the fabrication of very small structures that have features on the order of 100 nanometers or smaller. One application in which nano-fabrication has had a sizeable impact is in the processing of integrated circuits. The semiconductor processing industry continues to strive for larger production yields while increasing the circuits per unit area formed on a substrate; therefore nano-fabrication becomes increasingly important. Nano-fabrication provides greater process control while allowing continued reduction of the minimum feature dimensions of the structures formed. Other areas of development in which nano-fabrication has been employed include biotechnology, optical technology, mechanical systems, and the like.

An exemplary nano-fabrication technique in use today is commonly referred to as imprint lithography. Exemplary imprint lithography processes are described in detail in numerous publications, such as U.S. Patent Publication No. 2004/0065976, U.S. Patent Publication No. 2004/0065252, and U.S. Pat. No. 6,936,194, all of which are hereby incorporated by reference herein.

An imprint lithography technique disclosed in each of the aforementioned U.S. patent publications and patent includes formation of a relief pattern in a formable (polymerizable) layer and transferring a pattern corresponding to the relief pattern into an underlying substrate. The substrate may be coupled to a motion stage to obtain a desired positioning to facilitate the patterning process. The patterning process uses a template spaced apart from the substrate and a formable liquid applied between the template and the substrate. The formable liquid is solidified to form a rigid layer that has a pattern conforming to a shape of the surface of the template that contacts the formable liquid. After solidification, the template is separated from the rigid layer such that the template and the substrate are spaced apart. The substrate and the solidified layer are then subjected to additional processes to transfer a relief image into the substrate that corresponds to the pattern in the solidified layer.

### BRIEF DESCRIPTION OF DRAWINGS

So that features and advantages of the present invention can be understood in detail, a more particular description of embodiments of the invention may be had by reference to the embodiments illustrated in the appended drawings. It is to be noted, however, that the appended drawings only illustrate typical embodiments of the invention, and are therefore not to be considered limiting of its scope, for the invention may admit to other equally effective embodiments.

FIG. 1 illustrates a prior art versions of an interdigitated backside contact solar cell.

FIGS. 2A-2C illustrate simplified side and expanded vies of an exemplary interdigitated backside contact solar cell in accordance with the present invention.

FIGS. 3A-3B illustrate simplified side and expanded vies of another exemplary interdigitated backside contact solar cell in accordance with the present invention.

FIG. 4 illustrates a simplified side view of a lithographic system.

FIG. 5 illustrates a simplified side view of the substrate illustrated in FIG. 3, having a patterned layer thereon.

FIG. 6 illustrates a simplified side view of an exemplary template for using in forming an interdigitated backside contact solar cell having nanopatterns.

FIGS. 7A-7B illustrate a simplified side views of a substrate formed using the template illustrated in FIG. 6.

FIG. 8 illustrates a block diagram of an exemplary process for forming an interdigitated backside contact solar cell in accordance with the present invention.

### DETAILED DESCRIPTION

Nanopatterning may increase solar cell efficiency. For example, nano-imprint lithography may provide a low-cost method for enhancing efficiency while driving cost of ownership levels down. Nanopatterning has been shown in the prior art to reduce front surface reflection as well as allow for reduced reflection from backside contacts. During fabrication, however, additional lithography may be used to even further enhance efficiency.

Solar cells are generally formed having a p-type region and an n-type region. Adjacent p-type regions and n-type regions are known as PN junctions. Radiation on the solar cell results in electrons and holes migrating between p-type and n-type regions creating voltage differentials across PN junctions.

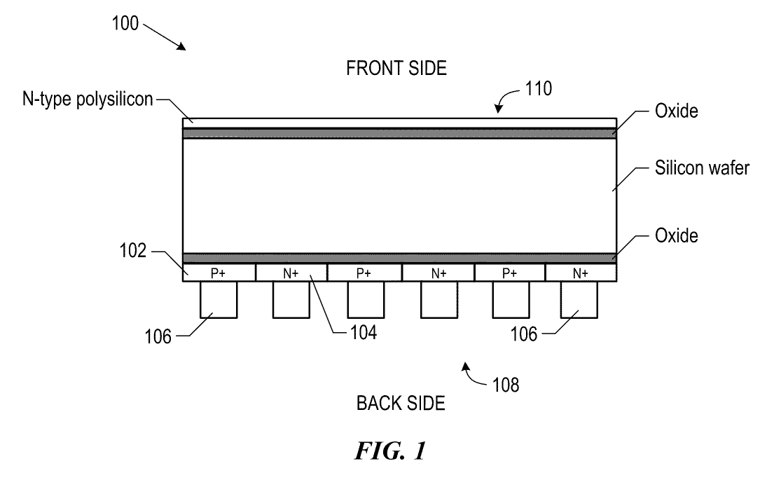

Referring to FIG. 1, an interdigitated back contact (IBC) solar cell 100 is a specific type of solar cell wherein p-type regions 102 and n-type regions 104 are generally coupled to metal contacts 106 on the back side 108 of the cell 100 as opposed to front side 110 of cell 100. Exemplary back side contact solar cells 100 are further described in U.S. Pat. No. 5,053,083, U.S. Pat. No. 4,927,770, and U.S. Pat. No. 7,633,006, which are hereby incorporated by reference in their entirety.

Prior art solar cells 100 including, but not limited to those listed herein, may be enhanced using nano-patterning techniques, specifically nanoimprint lithography. Current photolithography is generally limited to two dimensions or at most a grey scale. Nanoimprint, however, has been able to achieve three-dimensional patterning as it is essentially a molding process.

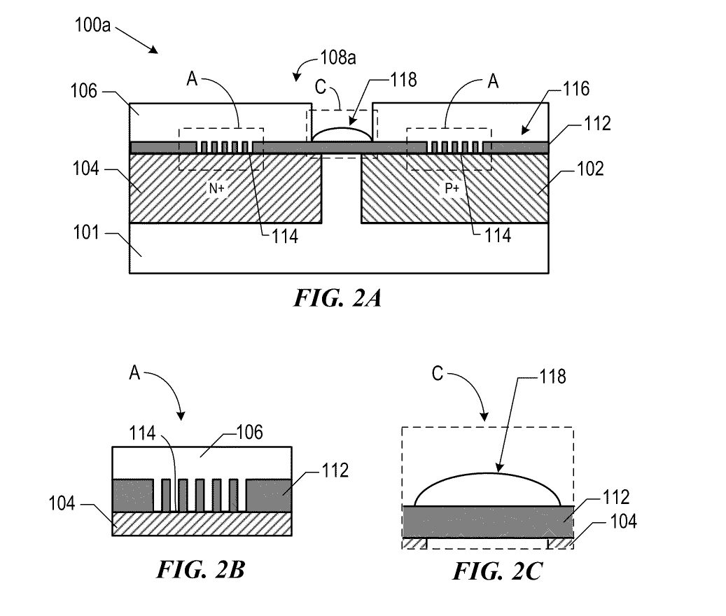

FIGS. 2A-2C illustrate an exemplary embodiment of a back side 108a of a solar cell 100a enhanced using nano-patterning techniques. Back side 108a of solar cell 100a may include p-region 102 positioned adjacent to n-region 104. A passivation layer 112 (e.g., SiO₂, SiN₂) may be positioned over p-region 102 and n-region 104 of semiconductor 101 such that passivation layer 112 is positioned between p-region 102/n-region 104 and metal contacts 106. Each metal contact 106 may be in superimposition with p-region 102 or n-region 104. Back side 108a of solar cell 108a may be enhanced by one or more of three different techniques described herein.

FIGS. 2A-2B illustrate a plurality of contact holes 114 formed in passivation layer 112 using nano imprint lithography techniques. Contact holes 114 provide contact between metal contacts 106 and p-region 102 or n-region 104. Using nano imprint lithography techniques, size of contact holes 114 may be reduced allowing for greater efficiency as compared to other techniques known within the art, such as contact hole formation using lasers, contact lithography, and the like. Further, the array of contact holes formed by nanoimprint lithography techniques may be formed into a light scattering pattern such as a 2D photonic crystal for increased light trapping and light scattering. Additionally, for increased light trapping and light scattering, the contact holes can have a pitch on the order of the wavelength(s) of interest. For example, the pitch of the contact holes can range from about 400 nm to about 1 um, with the holes themselves being smaller than the smallest pitch dimension, i.e., on the order of about 50 nm to about 200 nm in diameter.

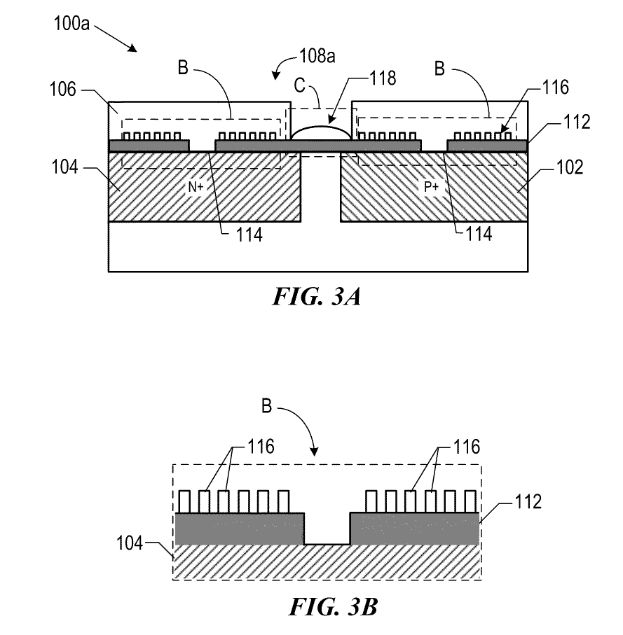

FIGS. 3A-3B illustrates formation of a texture pattern 116 on surface of passivation layer 112 in addition to formation of contact hole 114. Contact hole 114 and texture pattern 116 may be formed in a single lithography step as described in further detail herein. Texture pattern 116 may provide increased light trapping/scattering for cell 100a. Further, use of texture pattern 116 may be beneficial as the trend of using thinner silicon layer in solar cells continues.

FIG. 2C illustrates formation of an interdigitated contact resist 118 formed between metal contacts 106. Interdigitated contact resist can be formed by patterning the resist using nanoimprint lithography patterning techniques, or alternatively through deposition of resist after patterning, as is described below.

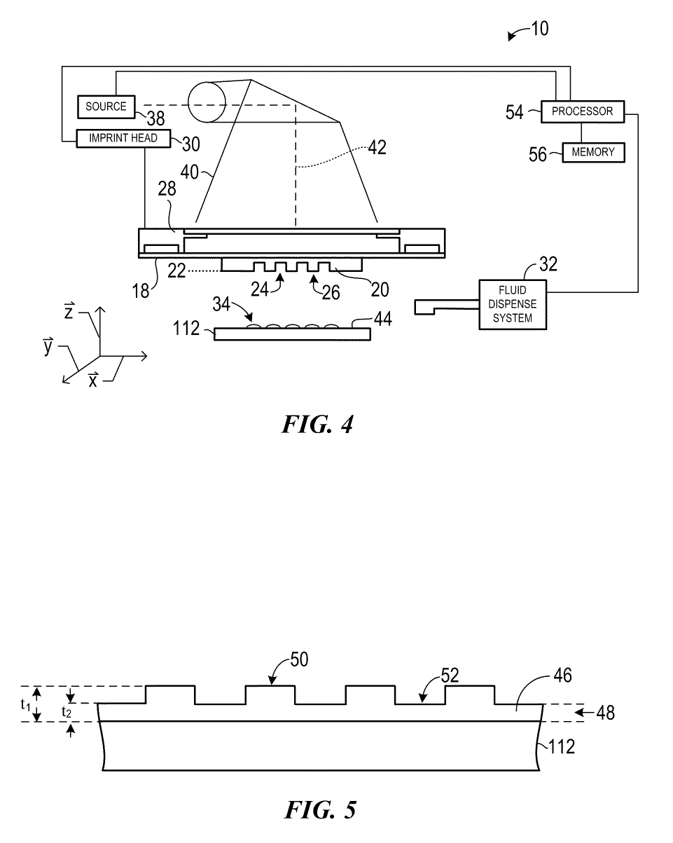

Referring to FIGS. 4 and 5, formation of solar cell 100a may be on a single tool in a single process using a lithographic system 10. Solar cell 100a may be loaded into system 10 and patterned for Section A and/or Section B of FIGS. 2 and/or 3, followed by formation of interdigitated contact resist 118 without unloading solar cell 100a from system 10.

During the lithography process, solar cell 100a may be coupled to a substrate chuck. Substrate chuck may be any chuck including, but not limited to, vacuum, pin-type, groove-type, electrostatic, electromagnetic, and/or the like. Exemplary chucks are described in U.S. Pat. No. 6,873,087, which is hereby incorporated by reference herein. Solar cell 100a and substrate chuck may be further supported by a stage. Stage may provide translational and/or rotational motion along the x, y, and z-axes. Stage, solar cell 100a, and/or substrate chuck may also be positioned on a base (not shown).

Spaced-apart from passivation layer 112 of solar cell 100a is template 18. Template 18 may include a body having a first side and a second side with one side having a mesa 20 extending therefrom towards passivation layer 112. Mesa 20 having a patterning surface 22 thereon. Further, mesa 20 may be referred to as mold 20. Alternatively, template 18 may be formed without mesa 20.

Template 18 and/or mold 20 may be formed from such materials including, but not limited to, fused-silica, quartz, silicon, organic polymers, siloxane polymers, borosilicate glass, fluorocarbon polymers, metal, hardened sapphire, and/or the like. As illustrated, patterning surface 22 comprises features defined by a plurality of spaced-apart recesses 24 and/or protrusions 26, though embodiments of the present invention are not limited to such configurations (e.g., planar surface). Patterning surface 22 may define any original pattern that forms the basis of a pattern to be formed on passivation layer 112. For example, template 18 shown in FIG. 4 may be used to form pattern in FIGS. 2A and 2B.

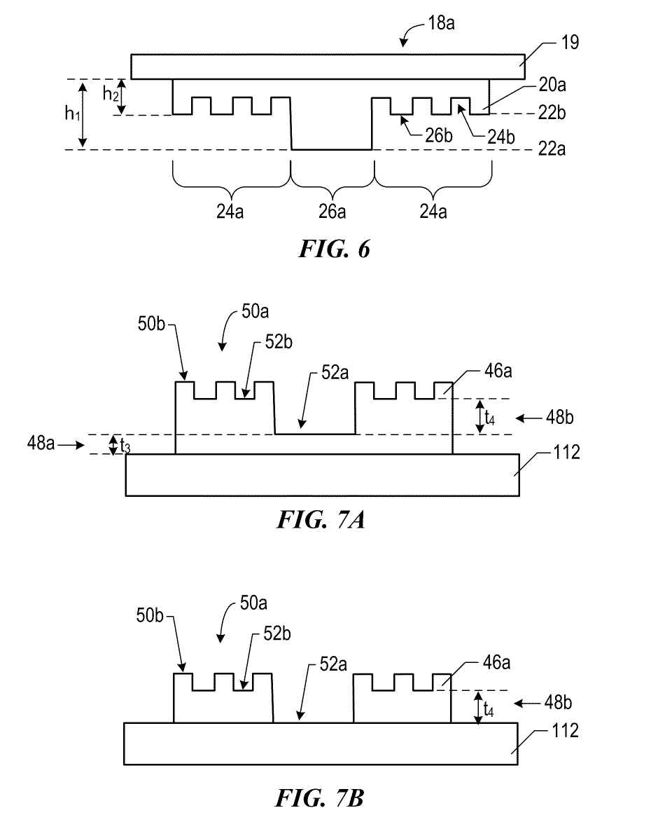

FIG. 6 illustrates an exemplary embodiment of template 18a that may be used to form the pattern provided in FIGS. 3A-3B. Pattern of template 18a may be configured such that a first set of features results in formation of contact holes 14 in passivation layer 106 and a second set of features results in formation of texture pattern 116 on passivation layer 112 in FIGS. 3A-3B. Template 18a may include a first set of features shown as protrusions 26a and recessions 24a having a first patterned surface 22a. Protrusions 26a may have a height h₁ extending from base 19 of template 18a. Within recessions 24a, a second set of features may be formed, protrusions 26b and recessions 24b providing patterned surface 22b. Protrusions 24b may extend a height h₂ from base 19 of template 18a. Height h₁ may be substantially larger than height h₂. Template 18a may be used in a similar manner as template 18 described below.

Referring again to FIGS. 4 and 5, template 18 may be coupled to chuck 28. Chuck 28 may be configured as, but not limited to, vacuum, pin-type, groove-type, electrostatic, electromagnetic, and/or other similar chuck types. Exemplary chucks are further described in U.S. Pat. No. 6,873,087, which is hereby incorporated by reference herein. Further, chuck 28 may be coupled to imprint head 30 such that chuck 28 and/or imprint head 30 may be configured to facilitate movement of template 18.

System 10 may further comprise a fluid dispense system 32. Fluid dispense system 32 may be used to deposit formable material 34 (e.g., polymerizable material) on passivation layer 112. Formable material 34 may be positioned upon passivation layer 112 using techniques, such as, drop dispense, spin-coating, dip coating, chemical vapor deposition (CVD), physical vapor deposition (PVD), thin film deposition, thick film deposition, and/or the like. Formable material 34 may be disposed upon passivation layer 112 before and/or after a desired volume is defined between mold 22 and passivation layer 112 depending on design considerations. Formable material 34 may be functional nano-particles having use within the solar cell industry, and/or other industries requiring a functional nano-particle. For example, formable material 34 may comprise a monomer mixture as described in U.S. Pat. No. 7,157,036 and U.S. Patent Publication No. 2005/0187339, both of which are herein incorporated by reference. Alternatively, formable material 34 may include, but is not limited to, solar cell materials, and/or the like. In one example, formable material 34 may be selected to provide a similar or different index of refraction as compared to metal contact 106.

Referring to FIGS. 4 and 5, system 10 may further comprise energy source 38 coupled to direct energy 40 along path 42. Imprint head 30 and stage 16 may be configured to position template 18 and passivation layer 112 in superimposition with path 42. System 10 may be regulated by processor 54 in communication with stage 16, imprint head 30, fluid dispense system 32, and/or source 38, and may operate on a computer readable program stored in memory 56.

Either imprint head 30, stage 16, or both vary a distance between mold 20 and passivation layer 112 to define a desired volume therebetween that is filled by formable material 34. For example, imprint head 30 may apply a force to template 18 such that mold 20 contacts formable material 34. After the desired volume is filled with formable material 34, source 38 produces energy 40, e.g., ultraviolet radiation, causing formable material 34 to solidify and/or cross-link conforming to a shape of surface 44 of passivation layer 112 and patterning surface 22, defining patterned layer 46 on passivation layer 112. Patterned layer 46 may comprise a residual layer 48 and a plurality of features shown as protrusions 50 and recessions 52, with protrusions 50 having a thickness t₁ and residual layer having a thickness t₂.

The above-mentioned system and process may be further employed in imprint lithography processes and systems referred to in U.S. Pat. No. 6,932,934, U.S. Pat. No. 7,077,992, U.S. Pat. No. 7,179,396, and U.S. Pat. No. 7,396,475, all of which are hereby incorporated by reference in their entirety.

Referring to FIGS. 2A, 2B and 5 features 50 and 52 of patterned layer 46 may be etched into passivation layer 112 forming contact holes 114 using known etching techniques within the industry forming contact holes 114 as illustrated in FIG. 2B. Metal contact 106 may then be deposited thereon.

Referring to FIGS. 3A, 3B, 6 and 7A, patterned layer 46a may be formed using template 18a illustrated in FIG. 6 to provide pattern in FIGS. 3A and 3B. Patterned layer 46a may include a first residual layer 48a having a thickness t₃, and a first set of features shown as protrusions 50a and recessions 52a. Additionally, patterned layer 46a may include a second residual layer 48b having a thickness t₄ and a second set of features shown as protrusions 50b and recessions 52b. The first set of features when exposed to an etching process results in formation of contact holes 14 in passivation layer 112, as shown in FIG. 7B, and the second set of features when exposed to the etching process results in formation of texture pattern 116 on passivation layer 112 illustrated in FIGS. 3A-3B.

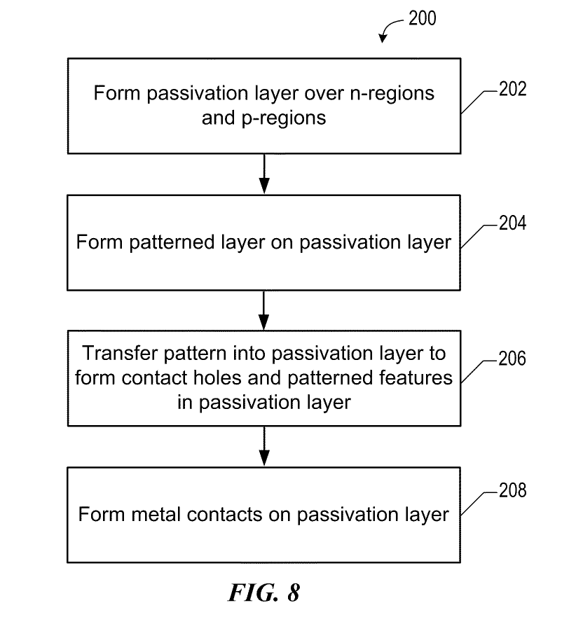

Interdigitated backside (IBC) solar cells as described herein can be fabricated by process 200 illustrated in the flowchart of FIG. 8. In step 202, passivation layer (e.g., SiO₂, SiN₂) is formed over alternating n-regions and p-regions on a semiconductor substrate. In step 204, a patterned layer is then formed over the passivation layer using nanoimprint lithography techniques. In step 206, the pattern is transferred into the passivation layer to form contact holes extending through and/or pattern features in the passivation layer. In step 208, metal contacts are formed on the passivation layer and contact the underlying n-regions and p-regions through the formed contact holes.

Nanopatterns may be transferred using wet or dry etching equipment and processes. Alternatively, nanopatterns may be transferred using techniques including VUV lamp exposure for atmospheric etching. Additionally surface wetting characteristics of patterned layers may be modified through UV ozone, oxygen ashing, or the like. By modifiying the surface wetting characteristics of the patterned layer formed on passivation layer, the lateral displacement and thus the resulting line width of the contact resist deposited as “C” in FIG. 2A (see also FIG. 2C) can be controlled. For example, prior to UV ozone exposure, the linewidth is larger than after UV ozone exposure, which reduces wettability of the patterned layer. A decreasing linewidth can allow for fabrication of closer pitch electrodes and thus yield solar cells having higher efficiencies.

Referring to FIGS. 2-3 and 4, in one embodiment, formable material 34 may be deposited on passivation layer 112 between metal contacts 106 and solidified without contact of template 18 and/or contact with a planar template in order to form contact resist 118. For example, a plurality of droplets (e.g., 6 pl) may be dispensed on passivation layer 112 and merged. Droplets may merge with or without use of a planar template. Once, merged, formable material 34 may be solidified. Deposition and solidification of formable material 34 without contact of template 18 (or contact with a planar template) may form interdigitated contact resist 118 between metal contacts 106 as shown in FIG. 2C.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description. Changes may be made in the elements described herein without departing from the spirit and scope as described in the following claims.

What is claimed is:

1. An interdigitated back contact (IBC) solar cell comprising:
a substrate having a front and a back side;
a plurality of adjacent p-regions and n-regions located on the back side;
metal contacts in superimposition with the p-type and n-type regions; and
a passivation layer formed between the metal contacts and the p-regions and n-regions, the passivation layer having a plurality of nanosized contact holes providing contact between the metal contacts and the p-regions and n-regions.

2. The solar cell of claim 1 wherein the plurality of contact holes are arrayed to form a light scattering pattern for increased light trapping/scattering.

3. The solar cell of claim 2 wherein the plurality of contact holes are arrayed to form a 2D photonic crystal.

4. The solar cell of claim 1 wherein the passivation layer further comprises a plurality of nanofeatures.

5. The solar cell of claim 4 wherein the plurality of nanofeatures provide a light scattering pattern.

6. The solar cell of claim 1 further comprising an interdigitated contact resist formed between metal contacts.

7. The solar cell of claim 1 wherein the contact holes have a pitch from about 400 nm to about 1 um, and diameters of about 50 nm to about 200 nm.

8. A method of forming an interdigitated back contact (IBC) solar cell comprising:
forming a passivation layer over n-regions and p-regions of a semiconductor substrate;
forming a patterned layer on the passivation layer;
transferring at least a portion the patterned layer to the passivation layer to expose a plurality of contact holes in the passivation layer;
forming metal contacts on the passivation layer, with the metal contacts contacting the n-regions and p-regions through the contact holes.

9. The method of claim 8 wherein the patterned layer is patterned such that contact holes formed by the transferring step are arrayed to form a light scattering pattern for increased light trapping/scattering.

10. The method of claim 9 wherein the formed contact holes are arrayed to form a 2D photonic crystal.

11. The method of claim 8 wherein the transferring step further provides a plurality of nanofeatures arrayed on the passivation layer.

12. The method of claim 11 wherein the formed array of nanofeatures provide a light scattering pattern.

13. The method of claim 8 further comprising forming an interdigitated contact resist between the metal contacts.

14. The method of claim 13 wherein the interdigitated contact resist is deposited on the patterned layer prior to forming the metal contacts.

15. The method of claim 14 further comprising modifying the surface wettability of the patterned layer prior to depositing the interdigitated contact resist on the patterned layer.

16. The method of claim 13 wherein the interdigitated contact resist is formed as part of the patterned layer forming step.
